(19) United States
(12) Patent Application Publication
(10) Pub. No.: US 2004/0256561 A1
(43) Pub. Date: Dec. 23, 2004

(54) Wide band light sensing pixel array

(76) Inventors: Allyson Beuhler, Woodridge, IL (US); Francisco Castro, Saint Charles, IL (US); Wanqing Li, Oatley (AU)

Correspondence Address: MOTOROLA, INC., 1303 EAST ALGONQUIN ROAD, IL01/3RD, SCHAUMBURG, IL, 60196

(21) Appl. No.: 10/463,032

(22) Filed: Jun. 17, 2003

(51) Int. Cl. G01J 5/02

(52) U.S. Cl. 250/339.05; 250/332

(57) ABSTRACT

In a wide band light sensing pixel array (100) comprising pixel groups (105), a ratio of a visible exposure period to a near infrared exposure period is controlled by a control circuit (108) to be essentially equivalent to a ratio of a second nominal sensitivity to a first nominal sensitivity. The visible exposure period is an exposure period of a set of visible light pixels having the first nominal sensitivity. The near infrared exposure period is an exposure period of a near infrared light pixel having the second nominal sensitivity. A subset of the set of visible light pixels and the near infrared light pixel in each pixel group (105) and circuit components associated only with the subset can be turned off during a reduced color mode.

### FIELD OF THE INVENTION

This invention relates generally to image sensors, and more particularly to image sensors based on integrated circuits fabricated with complementary metal oxide semiconductor (CMOS) technology.

### BACKGROUND

Digital imagers using charge coupled devices (CCDs) or complementary metal oxide semiconductor (CMOS) sensors are of great interest in security (for example, face recognition, face tracking), automotive safety (object classification, pedestrian recognition, lane tracking), and medical diagnostic techniques such as endoscopy where visual images can give early indications of malignant tissue. A major limitation in many of these systems is the high failure rate (including false negative and false positive responses) caused by the systems being unable to extract sufficient spectral information (for example, to differentiate debris from a pedestrian) from a 2-D visual image, or excessive complexity of the imaging system.

In some military and scientific applications, sufficient information content is obtained by using multiple sensors to generate separate spectral images over a wide band that includes the visible and near infrared spectrum, with identical perspective, scale, and registration. The multiple spectral images are then integrated into a single wideband image by superimposing thermal features from the infrared with the visible spatial information, thus allowing less ambiguous identification of the observed object. A similar strategy is used in endoscopy where outputs from two cameras (one sensitive in the green wavelength region and one sensitive in the red) are combined to differentiate malignant tissue cells from normal tissue.

These systems require multiple sensors (or a sensor combined with a spectrometer), exotic semiconductor technology for imaging the infrared, and complex image processing schemes to superimpose multiple images.

Two documents that refer to systems using a spectrometer coupled with a CCD imaging device are U.S. Pat. No. 6,276,798 issued to Gil et al. on Aug. 21, 2001, entitled “Spectral Bio-Imaging of the Eye” and “Modeling of skin reflectance spectra” authored by Meglinsky et al., and published on May 2001 in the Proc. SPIE Vol. 4241, pp. 78-87. As alluded to above, these types of systems can generate a plurality of frames of an image at differing spectral bands of interest, but which are complicated and expensive due primarily to the spectrometer.

Documents that refer to systems that can obtain multiple frames of an image at two or more bands of infrared energy are U.S. Pat. No. 6,370,260 issued to Pavlidis et al. on Apr. 9, 2002, entitled “Near-IR Human Detector” (also referred to herein as the '260 patent), and U.S. Pat. No. 6,420,728 issued to Razeghi on Jul. 16, 2002, entitled “Multi-Spectral Quantum Well Infrared Photodetector” (Also referred to herein as the '728 patent). The '260 patent uses two cameras to obtain two images of a scene filtered at two infrared wavelength bands (0.8 to 1.4 microns and 1.4 to 2.2 microns), and processes the two images to fuse them together. This is computationally intensive and expensive to implement. The '728 patent describes a technique for fabricating a photodetector that produces an output based on the combined energy incident upon the active circuit within a plurality of bands of the infrared portion of the electromagnetic spectrum, but the design described uses relatively expensive compound semiconductor material combinations that are responsive only to infrared energy.

What is needed is a cost effective technology for generating a frame of an image that includes wideband (i.e., at least visible and near infrared) information.

### BRIEF DESCRIPTION OF THE DRAWINGS

The present invention is illustrated by way of example and not limitation in the accompanying figures, in which like references indicate similar elements, and in which:

FIG. 1 is a plan view showing a wide band light sensing pixel array, in accordance with the preferred embodiment of the present invention;

FIG. 2 is a plan view of one pixel group of the image sensor shown in FIG. 1, in accordance with the preferred embodiment of the present invention;

FIG. 3 is an electrical schematic and block diagram of a pixel group, in accordance with the preferred embodiment of the present invention;

FIGS. 4 and 5 are graphs having plots of reverse voltages across a photosensitive diode versus exposure time, in accordance with the preferred embodiment of the present invention;

FIG. 6 is an electrical schematic and block diagram of a pixel measurement circuit, in accordance with the preferred embodiment of the present invention;

FIG. 7 is a plan view of one pixel group, in accordance with the preferred embodiment of the present invention; and

FIG. 8 is a flow chart of a method used in a wide band light sensing pixel array, in accordance with the preferred embodiment of the present invention.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION OF THE DRAWINGS

Before describing in detail the particular light sensing pixel array in accordance with the present invention, it should be observed that the present invention resides primarily in combinations of apparatus components related to a light sensing pixel array. Accordingly, the apparatus components and method steps have been represented where appropriate by conventional symbols in the drawings, showing only those specific details that are pertinent to understanding the present invention so as not to obscure the disclosure with details that will be readily apparent to those of ordinary skill in the art having the benefit of the description herein.

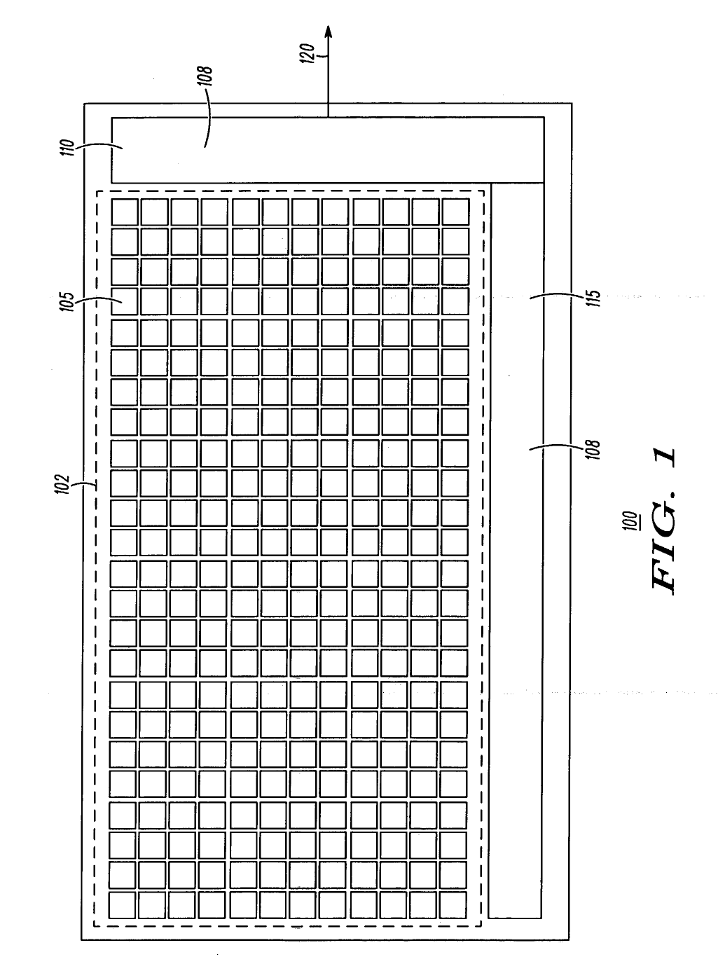

Referring to FIG. 1, a plan view shows a wide band light sensing pixel array 100 in accordance with the preferred embodiment of the present invention. The wide band light sensing pixel array 100 comprises a set of pixel groups 102 and control circuit areas 110, 115. The set of pixel groups 102 comprises pixel groups 105 formed in an array that are electrically coupled to a control circuit 108 located in the control circuit areas 110, 115. The control circuit 108 collects information from the pixel groups 105 to form a frame of an image, such as to generate a “still” picture, or to form periodic frames to form a video image. The frames are coupled by a signal 120 to a frame memory or another processor (not shown in FIG. 1).

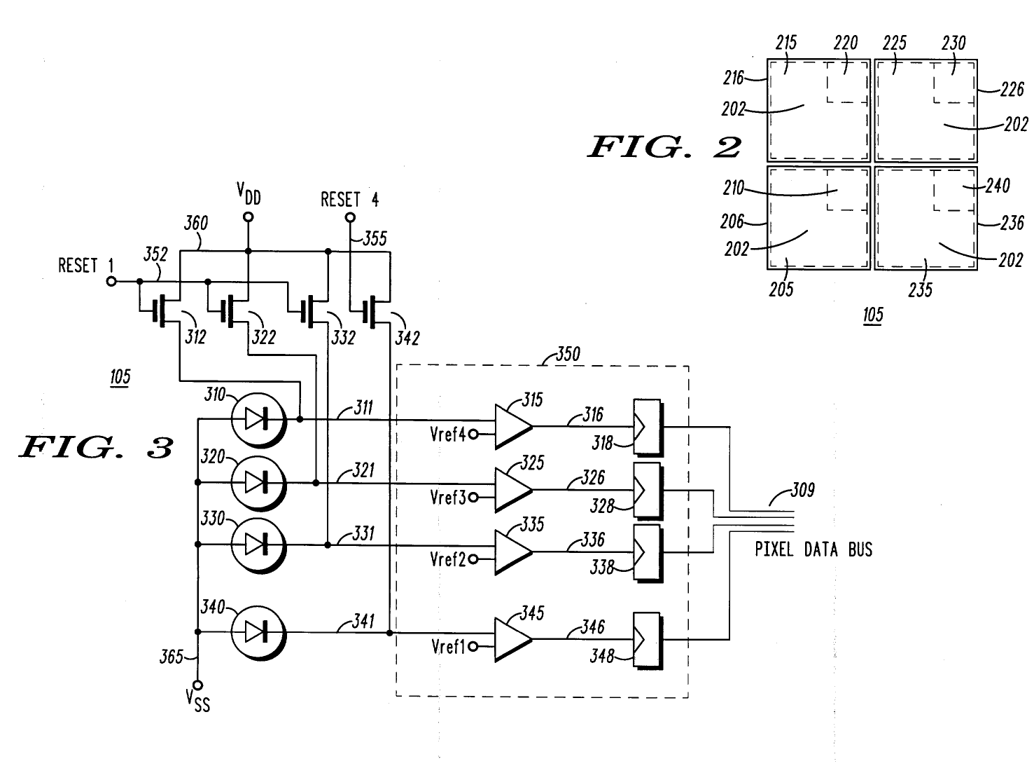

Referring to FIG. 2, a plan view of one of the pixel groups 105 in the set of pixel groups 102 of the wide band light sensing pixel array 100 is shown, in accordance with the preferred embodiment of the present invention. The pixel group 105 comprises a set of visible light pixels comprising a set of CMOS photodetectors 205, 215, 225 and a corresponding set of monochromatic pixel light filters 206, 216, 226 of different visible light bands, each monochromatic pixel light filter located in front of each corresponding CMOS photodetector. Each CMOS photodetector 205, 215, 225 comprises a photosensitive silicon diode junction (photodiode) area 202. Each monochromatic pixel light filter covers at least the photosensitive area 202 of one of the CMOS photodetectors 205, 215, 225. As a result of the combination of the monochromatic pixel light filter and the corresponding CMOS photodetector, each visible light pixel detects light energy within a range of wavelengths, also called a light band, or color channel, that is preferably identified as being associated with one of the visible colors blue, green and red. For example, the photodetector 205 is a blue photodetector, the photodetector 215 is a green photodetector, and the photodetector 225 is a red photodetector. Included within the area of each CMOS photodetectors 205, 215, 225 is an area that includes a pixel circuit 210, 220, 230. Each pixel circuit 210, 220, 230 includes electronic components that are coupled to the silicon photodetector, which convert an analog signal produced by the light incident on the photodetector to a digital electrical signal, called the visible light output signal. The pixel circuits 210, 220, 230 are typically identical or very similar to each other.

The pixel group 105 is unique in that it further comprises a near infrared light pixel comprising a CMOS photodetector 235 and a near infrared pixel light filter 236 located in front of the CMOS photodetector 235. The CMOS photodetector 235 comprises a silicon photodetector having a photosensitive silicon diode junction (photodiode) area 202. The range of light wavelengths that is called infrared, and the sub range of light wavelengths called near infrared, are not precisely defined, but infrared is generally accepted as having wavelengths from about 0.780 microns—the low frequency end of the visible light spectrum—to somewhere in the range from 5 to 10 microns, while near infrared is generally accepted as having wavelengths from about 0.780 microns to something over 1 micron. For this invention, the wavelengths included in near infrared are those wavelengths to which the light pixel comprising the CMOS photodetector 235 and the near infrared pixel light filter 236 can obtain a measurable response within a duration that is practical for the intended use (e.g., moving object versus still object). The range can be as narrow as a practical filter can be made without limiting the overall transmissivity. The longer wavelength end of the range is limited, among other things, by the sensitivity of the CMOS photodetector and by the transmissivity of the near infrared pixel light filter to longer wavelengths. Included within the area of the CMOS photodetectors 235 is an area that includes a pixel circuit 240. The pixel circuit 240 includes electronic components that are coupled to the silicon photodetector, which convert an analog signal produced by the light incident on the photodetector to a digital electrical signal, called the near infrared light output signal.

The visible light output signals and near infrared light output signals are coupled to the control circuit 108 by column/row matrix addressing that may be of conventional or unique design. The control circuit 108 then processes the visible light output signals and near infrared light output signals from all the pixel groups 105 to generate the frame image signal 120.

Each of the visible and infrared light pixels is preferably designed to be from approximately 3 to 20 micrometers on a side, for typical imaging applications, and the arrangement of the four light pixels with respect to each other is fairly arbitrary. The visible light filters 206, 216, 226 and the infrared light filters 236 of the set of pixel groups 102 are preferably fabricated using a dye patterned photo resist, but the invention is not restricted to that technology.

Referring to FIG. 3, an electrical schematic and block diagram of the pixel group 105 is shown, in accordance with the preferred embodiment of the present invention. The CMOS photodetectors 205, 215, 225 of the set of visible light pixels comprise a blue photodiode 310, a green photodiode 320 and a red photodiode 330 and three photodiode reset transistors: a blue photodiode reset transistor 312, a green photodiode reset transistor 322, and a red photodiode reset transistor 332. Each of the photodiodes 310, 320, 330 is substantially responsive to light that is within the color band that correspond to its respective name, and substantially non-responsive to light in other color bands, due to the corresponding visible light filters 206, 216, 226 (FIG. 2). In the circuit illustrated in FIG. 3, the cathode of the blue photodiode 310 is coupled to a first visible light output signal 311 and to an output terminal of the blue photodiode reset transistor 312. The cathode of the green photodiode 320 is coupled to a second visible light output signal 321 and to an output terminal of the green reset transistor 322. The cathode of the red photodiode 330 is coupled to a third visible light output signal 331 and to an output terminal of the red reset transistor 332. A first fixed reference voltage, V_{dd}, is coupled to a supply terminal 360 of the blue, green, and red reset transistors 312, 322, 332. The fixed reference voltage V_{dd} is positive with reference to a second fixed reference voltage, Vₛₛ, that is coupled to the anodes of the blue, green, and red photodiodes 310, 320, 330. An inverse of a first reset signal 352, that is binary, is coupled to reset inputs of the blue, green and red reset transistors 312, 322, 332 from the control circuit 110, which generates the first reset signal 352.

The CMOS photodetector 235 of the near infrared light pixel comprises an infrared photodiode 340 and a near infrared photodiode reset transistor 342. The photodiode 340 is substantially responsive to light that is within the color band that correspond to its respective name, and substantially non-responsive to light in other color bands, due to the corresponding near infrared light filter 236 (FIG. 2). The cathode of the infrared photodiode 310 is coupled to a near infrared light output signal 341 and to an output terminal of the near infrared photodiode reset transistor 342. The first fixed reference voltage, V_{dd}, is coupled to a supply terminal 360 of the near infrared reset transistor 342. The second fixed reference voltage, Vₛₛ, is coupled to the anode of the near infrared photodiode 340. An inverse of a second reset signal 355, that is binary, is coupled to a reset input of the near infrared reset transistor 342 from the control circuit 110, which generates the second reset signal 355.

When the first reset signal is asserted (i.e., when the voltage is a digital “high” voltage), the blue, green, and red reset transistors 312, 322, 332 conduct and the blue, green and red photodiodes 310, 320, 330 are all reversed biased with V_{dd}-Vₛₛ volts. When the first reset signal is unasserted, light energy within the bands of the blue, green, and red visible filters 206, 216, 226 (FIG. 2) causes the charge stored in the junction capacitance to be dissipated by reverse leakage of the blue, green and red photodiodes 310, 320, 330, causing the voltage at the cathodes of the photodiodes (alternatively called the reverse bias voltage potential or the reverse voltage across the photodiode) 310, 320, 330 to decrease with reference to the voltage at the anodes. The voltages at the cathodes of the photodiodes 310, 320, 330 are the values of the first, second, and third output signals 311, 321, 331. The decrease of the reverse voltage across a particular photodiode 310, 320, 330 occurs at a rate largely determined by the intensity (power) of light within the color band of the light impinging upon the active portion of the sensing area of the corresponding photodiode 310, 320, 330, the sensitivity of the corresponding photosensitive area 202, and the junction capacitance of the corresponding photodiode 310, 320, 330—until a junction voltage is reached at which the corresponding photodiode becomes sufficiently forward biased. The rate of voltage change is monotonic and nearly linear over a wide range, and can therefore be approximated by a slope of a line. Differences in the in-band transmissivities of the visible light filters 206, 216, 226 and differing sensitivities of the photosensitive areas to differing wavelengths of light will typically cause different nominal sensitivities of the complete CMOS photodetectors 205, 215, 225 that include the visible light filters 206, 216, 226.

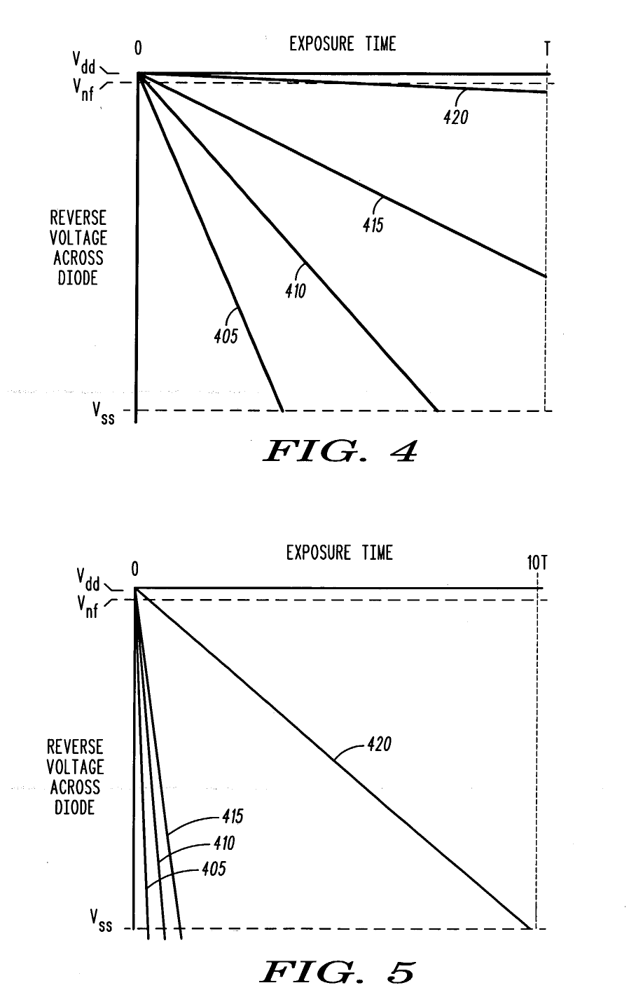

This is illustrated in FIG. 4, which shows plots 405, 410, 415 of the output values of the first, second, and third output signals 311, 321, 331, which are collectively called the set of visible output signals 311, 321, 331, versus time, when white light is incident on a pixel group 105. A nominal sensitivity of the visible light pixels can be measured using this white light. In FIG. 4, it can be seen that there is a variation of the nominal sensitivities of the visible light pixels, which is due to the different in-band sensitivities of the visible light filters 206, 216, 226 and CMOS photodetectors 205, 215, 225. A nominal sensitivity of each visible light pixel of the wide band visible light sensor array 100,is calibrated during a setup procedure or a design procedure. This calibration may determine a plurality of common nominal sensitivities, each of which can be used for all pixels of a same color band. Then, during normal operation, each measured slope of the visible light output signals 311, 321, 331 can be compared to each nominal sensitivity to determine the energy of the light within each of the three light bands that is detected by the photosensitive area 202 of each of the visible light photodiodes 310, 320, 330 during a visible exposure period (such as T in FIG. 4). The visible exposure period is the duration of the unasserted state of the first reset signal 352.

At the time scale used in FIG. 4, the slopes of the plots of the set of visible light output signals 405, 410, 415 versus time are of a similar order of magnitude. In accordance with the preferred embodiment of the present invention, the set of visible light pixels is characterized by a first nominal sensitivity that is preferably the arithmetic average of the nominal sensitivities of each of the visible light pixels. For example, the approximate nominal sensitivities of each of the visible light pixels in the set of visible light pixels, as illustrated by plots 405, 410, 415, are 0.5, 1.15, and 2.5, so a nominal sensitivity of the set of visible light pixels is 1.38. Other techniques could be used to obtain the nominal sensitivity for the set (e.g., the median value could be used). This first nominal sensitivity for the set of visible color bands can be used to determine the visible exposure period, which in FIG. 4 is shown as T, by using the relationship Exposure_{visible}=Vₘₐₓ/(nominal visible sensitivity). Vₘₐₓ is the maximum measurable voltage range, and is approximated by V_{nf}-Vₛₛ, where V_{nf} is a well known noise voltage level slightly below V_{dd}. So, in the example of FIG. 4, Exposure_{visible}=(V_{nf}-Vₛₛ)/1.38=T.

When the second reset signal is asserted (i.e., when the voltage is a digital “high” voltage), the near infrared reset transistor 342 conducts and the near infrared photodiode 340 is reversed biased with V_{dd}-Vₛₛ volts. When the near infrared reset signal is unasserted, light energy within the band of the near infrared visible filter 236 (FIG. 2) causes the charge stored in the junction capacitance to flow into the anode of the near infrared photodiode 340 causing the reverse voltage across the photodiode 340 to decrease with reference to the voltage at the anode. The decrease of the reverse voltage across the infrared photodiode 340 occurs at a rate largely determined by the intensity (power) of light within the color band of the light impinging upon the active portion of the sensing area of the infrared photodiode 340, the sensitivity of the corresponding photosensitive area 202, and the junction capacitance of the corresponding photodiode 340—until a junction voltage is reached at which the corresponding photodiode becomes sufficiently forward biased. The rate of voltage change is monotonic and nearly linear over a wide range, and can therefore be approximated by a slope of a line. When the photosensitive areas 202 (FIG. 2) are the same size and fabricated at the same time on the same integrated circuit die, which is in accordance with the preferred embodiment of the present invention, the sensitivities of the photosensitive areas 202 are approximate the same for different color bands of the visible light badn. However, a substantial difference in the in-band transmissivity of the near infrared light filter 236 in comparison to the transmissivities of the visible light filters 206, 216, 226 causes a substantially lower nominal sensitivity of the complete CMOS photodetector 235 that includes the near infrared light filter 236 (the silicon also affects the sensitivity, not just the filter).

This is also illustrated in FIG. 4, which shows a plot of the output value 420 of the near infrared output signal 341 versus time when “white” light at a relatively high expected brightness is incident on a pixel group 105, in accordance with the preferred embodiment of the present invention. A nominal sensitivity of the near infrared light pixel can be measured using this white light.

In FIG. 4, it can be seen that the slope of the near infrared output signal 341 versus time is nearly flat when plotted on the time scale used in FIG. 4. A problem in past imaging devices is that a common exposure period has typically been used for all pixels. This would make the measurement of the near infrared light energy very inaccurate, as indicated in FIG. 4 by the small slope of the plot 420 of the near infrared output value. But by uniquely separating the exposure periods for the visible light pixels and the near infrared light pixels, a different exposure period can be used for the near infrared light pixel and an accurate measurement of the near infrared light intensity can be obtained. The approximate nominal sensitivity of the infrared light pixel, as illustrated by plot 420, is 0.14. Using the same approach as used for determining the visible light exposure period, Exposure_{near infrared}=(V_{nf}-Vₛₛ)/0.14, which is approximately 10 T. The control circuit 110 determines this ratio automatically, or it can be manually set in the control circuit 110 by an operator. This is illustrated in FIG. 5, in which the near infrared exposure period, which is the duration of the, unasserted state of the second reset signal, is set to 10 T. Using a substantially different duration for the near infrared exposure period for the near infrared pixel and the visible exposure period for the visible pixels, accurate measurements can be obtained for the component bands of light in wide bandwidth light spanning the wavelengths from blue to near infrared over a broad range of intensities of incident light. By “substantially different duration” is meant a ratio that is 3:1 or higher.

After calibrating the nominal sensitivity of the near infrared light pixel, a measured slope of the near infrared light output signal 341 can be compared to the nominal sensitivity of the near infrared light pixel to determine the amount of energy of the light within the near infrared light band that is detected by the photosensitive area 202 of the near infrared light photodiodes 340 during the near infrared exposure period (such as 10 T in FIG. 5).

Referring again to FIG. 3, the set of visible light output signals 311, 321, 331 and the infrared light output signal 341 are coupled to a pixel measurement circuit 350 that comprises a set of individual pixel circuits, each being a part of one of the pixel circuits 210, 220, 230 240. In this exemplary embodiment of the present invention, each individual pixel circuit comprises a comparator 315, 325, 335, 345, the output 316, 326, 336, 346 of which is coupled to a corresponding digital counter 318, 328, 338, 348, and one input of which is one of the light output signals 311, 321, 331, 341. Each comparator 315, 325, 335, 345 has a corresponding reference voltage, V_{Ref4}, V_{Ref3}, V_{Ref2}, V_{Ref1} that is generated by the control circuit 108 coupled to it as a comparison input. Each comparator's output 316, 326, 336, 336 is in a first binary state (e.g., low, or 0) when the light output signal 311, 321, 331, 341 coupled to that comparator is less than the reference voltage coupled to that comparator, and otherwise is in a second binary state (e.g., high, or 1). During the visible exposure period, the reference voltages V_{Ref4}, V_{Ref3}, V_{Ref2} are set to a value within the range V_{nf}-Vₛₛ, that is determined from previous frame measurements. At the end of each of a predetermined number of equal visible time intervals during the visible exposure time, when the output of one of the comparators 315, 325, 335 is in the first binary state, the corresponding digital counter 318, 328, 338 is incremented, and when the output is in the other binary state, the corresponding digital counter 318, 328, 338 is not incremented. At the end of the visible exposure time, then, each corresponding digital counter 318, 328, 338 contains a count of visible time intervals during which the corresponding visible light output signals 311, 321, 331 is less than the respective reference voltage V_{Ref4}, V_{Ref3}, V_{Ref2}. This information, herein called the wide band pixel information, is coupled to the control circuit 108 by pixel output signal 309. Thus, the pixel output signal 309 comprises a set of values based on the set of visible light output signals and the near infrared light output signal. From the wide band pixel information, a measured slope of the voltage versus time of each of the visible light output signals 311, 321, 331 is determined by the control circuit 108. By comparing the measured slope to the nominal sensitivity of the corresponding visible light pixel, the intensity of the light incident upon each light pixel of the set of visible light pixels can be established and an image frame generated by the control circuit 108

A similar technique is used to measure the slope of the near infrared light output signal 341, except that the near infrared exposure period and the near infrared equal time intervals used are different than the visible light exposure period and visible equal time intervals.

Wide band pixel information comprising the values in the counters at the end of each visible and near infrared exposure times is communicated to the control circuit 108 for fusing into an image frame. The fusing is done in a manner according to the environmental circumstances to present an enhanced image that presents more information to the user in an easy to use manner, without a user having to observe separate visible and near infrared images, without having to use complicated image stitching processing techniques, and while avoiding the problems associated with two images obtained having either parallax or time shift problems in them, while using accurate measurements of both visible and near infrared light. The wide band pixel information can be manipulated using techniques such as emphasizing edges, enhancing contrast, and eliminating background to enhance the image, which generally uses such fundamental functions as adding, subtracting, rating, or multiplying the wide band pixel (intensity) information.

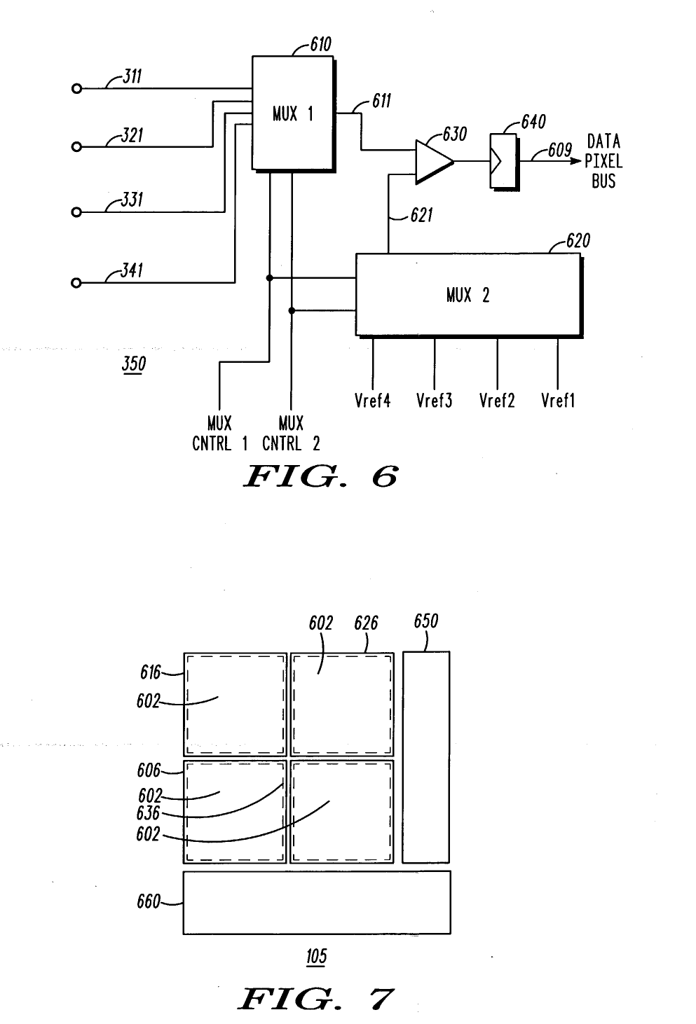

Referring to FIG. 6, an alternative version of the pixel measurement circuit 350 is shown, in accordance with the preferred embodiment of the present invention. In this alternate version, the set of visible light output signals 311, 321, 331 and the infrared light output signal 341 are multiplexed by multiplexer 610, the output 611 of which is coupled to one input of a comparator 630. The four reference voltages, V_{Ref4}, V_{Ref3}, V_{Ref2}, V_{Ref1} are synchronously multiplexed by multiplexer 620, the output of which is coupled to another input of the comparator 630. The wide band pixel information for one image frame is stored in multiple counter 640 (comprising four binary counters), and coupled by pixel output signal 609 to the control circuit 108 at times controlled by the control circuit 108. Thus, the pixel output signal 609 comprises a set of values based on the set of visible light output signals and the near infrared light output signal. Referring to FIG. 7, a plan view of one of the pixel groups 105 of the wide band light sensing pixel array 100 is shown for this alternate version of the pixel measurement circuit 350. In this plan view, the multiplexers 610, 620, the comparator 630, and the multiple counter 640 are located in the circuit areas 650, 660 of the pixel group 105 and the photosensitive areas 602 are in a square grouping, with the light filters 606, 616, 626, 636 covering the photosensitive areas 602. The reset transistors in this alternative version can still be located in the corners of each photosensitive area 602, or they can be located in the circuit areas 650, 660.

In these variations of the pixel measurement circuit 350, it will be appreciated that if, for example, each of the three visible colors and the near infrared band are measured with a: common amount of precision characterized by M bits, and if the ratio of the near infrared to visible exposure times is N, then the total number of bits per pixel group is (3N+1)M, and the total number of bits processed by the control circuit for one image frame is G(3N+1)M, where G is the number of pixel groups. In accordance with the preferred embodiment of the present invention, reduced color modes are defined in which a subset of the light pixels in each pixel group is used to generate the wide band pixel information. The unused light pixels are turned off. For example, in some circumstances, the near infrared information may not be needed. Then the total number of bits processed by the control circuit in one image frame is G(3N)M. In another example, perhaps only the red and infrared bands are valuable. Then the total number of bits processed by the control circuit in one image subframe is G(N+1)M, from which it can be seen that since fewer processing cycles can be used on the smaller amount of subframe data, the subframe period can be smaller than the frame period. Also the power consumed by the wide band light sensing pixel array 100 can be approximated by (CP+K), where C represents the number of light bands that are turned on, P represents the amount of power consumed by the light pixels of one light band (color), and K is constant amount of power for the control circuits that remain on for all light band modes. It will be appreciated that the power requirements of the wide band light sensing pixel array 100 can be substantially reduced when the number of light bands used in a reduced color mode is smaller than the maximum number of light bands, by turning off those light pixels and the circuits directly associated with those light pixels that are not needed for a particular reduced color mode. One means of doing this is by separating the first reset signal into three visible reset signals, one for each reset transistor 312, 322, 332, and to keep the reset signals for the unneeded light bands in the low state; and to simultaneously switch off power sources coupled to the circuit components associated with the unneeded light bands (for the example in FIG. 3, one or more of the comparators 315, 325, 335, 345 and digital counters 318, 328, 338, 348). In summary, the pixel measurement circuit 350 is coupled to the set of visible light output signals 311, 321, 331 and the near infrared output signal 341 and generates a pixel output signal 309, 609 that comprises a set of values based on a subset of light output signals selected from the set of visible light output signals 311, 321, 331 and the near infrared light output signal 341 that includes at least one light output signal. It will be appreciated that a subset of the set of visible light pixels and the near infrared light pixel and directly associated circuit components in each pixel group that are not members of the subset of selected light output signals are turned off during a reduced color mode.

It will be further appreciated that while the embodiments and variations of the present invention described above have included a set of visible light pixels in each pixel group that are sensitive to the light bands blue, green, and red, the set of visible light pixels in each pixel group could alternatively be made sensitive to light bands of cyan, yellow, and magenta in a wide band light sensing pixel array 100 that produces an image that includes “full visible color”, by using a dye patterned photo resist having filters made from dyes that pass the cyan, yellow, and magenta light bands. In another alternative, the wide band light sensing pixel array 100 could include pixel groups that include a visible light pixel of only one visible color and the near infrared light pixel in each pixel group. Thus, the set of visible light pixels can include any number of visible light bands more than zero. In instances when the set of visible light pixels is not three, the color pattern of the filters would necessarily be different than described with reference to FIGS. 2 and 7.

It will be appreciated that the visible and near infrared light pixels need not be arranged as shown in FIGS. 2 and 7; for example, the rows or columns could be offset with reference to each other. Furthermore, the shape of the visible and near infrared light pixels need not square as shown in FIGS. 2 and 7; for example, they could be rectangular or hexagonal. It will be further appreciated that the number of pixels in a pixel group could be other than the four described herein above. In some applications, It may be desirable to have more light bands, and the pixel groups could then be arranged, for example, in a 3×3 or 4×4 array. Some color bands might be repeated in a pixel group for improved resolution of a particular color. It will be further appreciated that while the CMOS photodetectors 235 are preferably silicon diode junctions coupled as shown in FIGS. 3 and 6, which rely on their junction capacitance as an integrating mechanism, there are many other combinations and couplings of electrical components with photosensitive silicon diode junctions that will provide light output signals that have the necessary characteristic of changing monotonically and nearly linearly in response to incident light of constant power, and any of these can be used in accordance the present invention. Thus the term CMOS photodetector in the context of this description means any such combination of a photosensitive silicon diode junction, and active and passive devices compatible with CMOS integration technology.

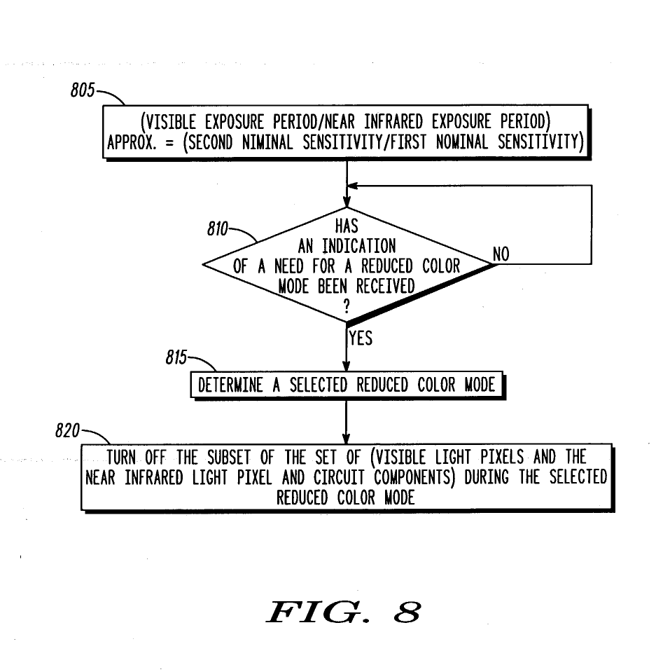

Referring to FIG. 8, a flow chart shows steps of a method used in a wide band light sensing pixel array. At step 805, a ratio of a visible exposure period to a near infrared exposure period is controlled by the control circuit 110 to be essentially equivalent to a ratio of a second nominal sensitivity to a first nominal sensitivity. The visible exposure period establishes an exposure period of a set of visible light pixels having the first nominal sensitivity that enables the visible light photodiodes 310, 320, 330 to generate a set of visible light output signals, each of which has an output value during the visible exposure period. The near infrared exposure period establishes an exposure period of a near infrared light pixel having the second nominal sensitivity that enables the infrared photodiode 340 to generate a near infrared output signal having an output value during the near infrared exposure period. At step 810, a determination is made by the control circuit 110 whether an indication of need for a reduced color mode. For example, there can be a operator selectable button or virtual button that indicates that a reduced color mode is desired. When such an indication is received by the control circuit 110 at step 810, then a particular reduced color mode is selected at step 815. This could be done, for example by the control circuit 110 presenting a list of possible reduced color modes on a display and determining by operator inputs which one is desired. It will be appreciated that in some applications, a reduced color mode could be automatically determined in response to environmental conditions and in that case, steps 810 and 815 could be combined into a step that simply detects the receipt of a reduced color command that indicates which reduced color mode is commanded. At step 820, a subset of the set of visible light pixels and the near infrared light pixel and circuit components in each pixel group associated only with the subset are turned off by control signals generated by the control circuit 110 during the indicated reduced color mode. In the foregoing specification, the invention and its benefits and advantages have been described with reference to specific embodiments. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention. The benefits, advantages, solutions to problems, and any element(s) that may cause any benefit, advantage, or solution to occur or become more pronounced are not to be construed as a critical, required, or essential features or elements of any or all the claims.

As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

The term “coupled”, as used herein with reference to any electro-optical technology, is defined as connected, although not necessarily directly, and not necessarily mechanically. The term “program”, as used herein, is defined as a sequence of instructions designed for execution on a computer system. A “program”, or “computer program”, may include a subroutine, a function, a procedure, an object method, an object implementation, an executable application, an applet, a servlet, a source code, an object code, a shared library/dynamic load library and/or other sequence of instructions designed for execution on a computer system.

What is claimed is:

1. A wide band light sensing pixel array comprising:
a set of pixel groups, each pixel group comprising
a set of visible light pixels comprising a set of CMOS photodetectors and a corresponding set of monochromatic pixel light filters of different visible light bands, wherein the set of visible light pixels has a first nominal sensitivity and generates a set of visible light output signals, each of which has an output value during a visible exposure period, and
a near infrared light pixel comprising a CMOS photodetector and a corresponding near infrared pixel light filter, wherein the near infrared light pixel has a second nominal sensitivity and generates a near infrared output signal having an output value during a near infrared exposure period; and
a control circuit coupled to the set of visible light output signals and to the near infrared output signal, that establishes a ratio of the infrared exposure period to the visible exposure period that is essentially equivalent to the ratio of the first nominal sensitivity to the second nominal sensitivity.

2. The wide band light sensing pixel array according to claim 1, wherein the set of CMOS photodetectors and the CMOS photodetector are arranged in an essentially co-planar configuration.

3. The wide band light sensing pixel array according to claim 1, wherein the ratio of the first nominal sensitivity to the second nominal sensitivity is at least three.

4. The wide band light sensing pixel array according to claim 1, wherein each output value of the visible light output signals increases in response to an intensity of light of one of the different visible light bands incident upon each of the monochromatic pixel light filters during the visible exposure period and the output value of the infrared light output signal increases in response to an intensity of near infrared light incident upon the near infrared pixel light filter during the near infrared exposure period.

5. The wide band light sensing pixel array according to claim 1, wherein the set of pixel groups and the control circuit are on a single CMOS integrated circuit.

6. The wide band light sensing pixel array according to claim 1, wherein the set of visible light pixels comprise three CMOS photodetectors and a corresponding set of red, green, and blue light filters.

7. The wide band light sensing pixel array according to claim 1, wherein the set of visible light pixels comprise three CMOS photodetectors and a corresponding set of cyan, yellow, and magenta light filters.

8. The wide band light sensing pixel array according to claim 1, wherein a subset of the set of visible light pixels and the near infrared light pixel and circuit components in each pixel group associated only with the subset are turned off during a reduced color mode.

9. The wide band light sensing pixel array according to claim 1, wherein a pixel measurement circuit coupled to the set of visible light output signals and the near infrared output signal generates a pixel output signal that comprises a set of values based on a subset of light output signals selected from the set of visible light output signals and the near infrared light output signal that includes at least one light output signal.

10. The wide band light sensing pixel array according to claim 9, wherein a subset of the set of visible light pixels and the near infrared light pixel and directly associated circuit components in each pixel group that are not members of the subset of selected light output signals are turned off.

11. The wide band light sensing pixel array according to claim 1, wherein each CMOS photodetector of the set of visible light pixels and the near infrared light pixels comprises an integrator.

12. The wide band light sensing pixel array according to claim 1, wherein each integrator comprises a junction capacitance of the CMOS photodetector.

13. A method used in a wide band light sensing pixel array comprising:
controlling a ratio of a near infrared exposure period to a visible exposure period to be essentially equivalent to a ratio of a first nominal sensitivity to a second nominal sensitivity,
wherein the visible exposure period is an exposure period of a set of visible light pixels having the first nominal sensitivity during which a set of visible light output signals, each of which has an output value, is generated, and
wherein the near infrared exposure period is an exposure period of a near infrared light pixel having the second nominal sensitivity during which a near infrared output signal having an output value is generated.

14. The method according to claim 13, wherein the ratio of the first nominal sensitivity to the second nominal sensitivity is at least three.

15. The method according to claim 13, further comprising:
turning off a subset of the set of visible light pixels and the near infrared light pixel and circuit components in each pixel group associated only with the subset during a reduced color mode.

16. The method according to claim 13, further comprising:
generating a pixel output signal that comprises a set of values based on a subset of light output signals selected from the set of visible light output signals and the near infrared light output signal that includes at least one light output signal.

17. The method according to claim 16, further comprising:
turning off a subset of the set of visible light pixels and the near infrared light pixel and directly associated circuit components in each pixel group that are not members of the subset of selected light output signals.
